(19) United States
(12) Patent Application Publication
(10) Pub. No.: US 2025/0301677 A1
(43) Pub. Date: Sep. 25, 2025

(54) INSULATED TURN-OFF DEVICE WITH REDUCED SENSITIVITY TO VARIATIONS IN TRENCH DEPTH

(71) Applicant: Pakal Technologies, Inc., SAN FRANCISCO, CA (US)

(72) Inventor: Paul M. Moore, Hillsboro, OR (US)

(73) Assignee: Pakal Technologies, Inc., SAN FRANCISCO, CA (US)

(21) Appl. No.: 19/082,597

(22) Filed: Mar. 18, 2025

Related U.S. Application Data
(60) Provisional application No. 63/567,258, filed on Mar. 19, 2024.

(51) Int. Cl. H10D 12/00; H01L 21/02; H01L 21/265; H10D 12/01; H10D 62/10; H10D 62/83; H10D 84/80

(52) U.S. Cl. CPC H10D 12/481; H01L 21/02318; H01L 21/26513; H10D 12/038; H10D 62/124; H10D 84/80; H10D 62/83

(57) ABSTRACT

In a trench-gated device, the effective depth of a gate-induced inversion layer into a p-body is made more consistent to make the operating characteristics of the device more consistent. In one example, the p-body is formed over an n-drift layer, and an n+ source layer is formed over the p-body. Trenches are then etched that extend through the p-body and into the n-drift layer. Next, a p-doped layer is grown or deposited in the trenches. In one embodiment, the p-doped layer remains in the trench. In another embodiment, the p-dopants in the layer are diffused into the trench walls, and the layer is removed. This added p-type layer in or around the trenches contacts the side of the p-body to effectively form a very controllable deeper portion of the p-body. A gate oxide is formed, and the insulated trenches are filled with a conductor, such as doped polysilicon.

### CROSS-REFERENCE TO RELATED APPLICATIONS

This application claims priority to U.S. provisional patent application Ser. No. 63/567,258, filed Mar. 19, 2024, by Paul M. Moore, assigned to the present assignee and incorporated herein by reference.

### FIELD OF THE INVENTION

This invention relates to vertical, insulated-gate controlled semiconductor devices that use an insulated trench filled with a conductor as the gate for operating the device. More particularly, the invention relates to a method and structure for reducing the sensitivity of the device to process-inherent variations in trench depth and/or p-body depth.

### BACKGROUND

The present disclosure is directed to improvements in the structure of vertical, insulated-gate-controlled devices, such as Insulated Gate Bipolar Transistors (IGBTs), Insulated Gate Turn-off Devices (IGTOs), thyristors, and other related devices that switch between an on state and an off state to control power to a load, such as a motor. One improvement achieved by the invention is a more consistent turn-on voltage from lot to lot.

An example of an IGTO device that can be improved by the present invention is described in the assignee's U.S. Pat. No. 8,878,237, incorporated herein by reference, summarized below.

FIG. 1 is a cross-section of a small portion of an IGTO device 10. The portion is near an edge of the device and shows a plurality of cells having vertical gates 12 (e.g., doped polysilicon) formed in insulated trenches, forming field effect devices. A 2-dimensional array of the cells may be formed in a common p-well 14, and the cells are connected in parallel. The p-well 14 may also be referred to as the p-base or p-body. The p-well 14 is typically formed by ion implantation followed by a drive-in step.

The area containing the cells is shown as the active region 15. The edge cell has an opening 16 in the n+ source region 18 where the cathode electrode 20 (or source electrode) shorts the n+ source region 18 to the p-well 14. Such shorting increases the tolerance to transients to prevent unwanted turn on (i.e., prevent high emitter-base voltages) and prevents the formation of hot spots. The removal of part of the n+ source region 18 in the edge cell also reduces the current near the edge. The edge cell may surround the active region 15, or there may be separate edge cells along two or more edges of the cell array.

The vertical gates 12 are insulated from the p-well 14 by an oxide layer 22. The narrow gates 12 are connected together outside the plane of the drawing and are coupled to a gate voltage via the gate electrode 25 contacting the polysilicon portion 28. A patterned dielectric layer 26 insulates the metal from the various regions. Field limiting rings 29 at the edge of the cell in the termination region 27 reduce field crowding, thereby increasing the breakdown voltage. The termination region 27 is designed to break down at a voltage higher than the breakdown voltage of the active region 15, since the cathode electrode 20 is over the active region 15 and can efficiently conduct the breakdown current. The termination region 27 surrounds the active region 15, which may have a generally rectangular shape. The active region 15 may take up the center area of a die or may be formed in strips separated by termination regions 27.

An npnp semiconductor layered structure is formed in FIG. 1. There is a bipolar pnp transistor formed by a p+ substrate 30, an n-epitaxial (epi) layer 32, and the p-well 14. The n-epi layer 32 can also be referred to as a drift layer that becomes depleted when the device is off, so as to increase the breakdown voltage. There is also a bipolar npn transistor formed by the n-epi layer 32, the p-well 14, and the n+ source region 18. An n-type buffer layer 35, which may be epitaxially grown or formed by implantation into the substrate 30, has a dopant concentration higher than that of the n-epi layer 32. The buffer layer 35 helps to set the breakdown voltage and reduces hole injection into the n-epi layer 32. A metal anode electrode 36 (or drain electrode) contacts the substrate 30, and a metal cathode electrode 20 (or source electrode) contacts the n+ source region 18. The p-well 14 surrounds the gate structure, and the n-epi layer 32 extends to the surface around the p-well 14.

When the anode electrode 36 is forward biased with respect to the cathode electrode 20, but without a sufficiently positive gate bias, there is no current flow, since the product of the betas (gains) of the pnp and npn transistors is less than one (i.e., there is no regeneration activity). This behavior is achieved by selecting the proper doping profile in the p-well 14.

When the gate is forward biased, electrons from the n+ source region 18 become the majority carriers along the gate sidewalls in an inversion layer, referred to as a “voltage induced emitter,” causing the effective width of the npn base (the portion of the p-well 14 between the n-layers) to be reduced. The inversion layer provides free electrons that are injected into the p-well 14. As a result, the beta of the npn transistor increases to cause the product of the betas to exceed one. This condition results in device turn-on, with holes being injected into the lightly doped n-epi layer 32 and electrons being injected into the p-well 14. Accordingly, the gate bias initiates the turn-on, and the full turn-on (due to regenerative action) occurs when there is current flow through both the npn transistor and the pnp transistor.

When the gate bias is removed, such as the gate electrode 25 being shorted to the cathode electrode 20, the IGTO device turns off.

FIG. 2 illustrates the relative doping concentrations vs. depth into the wafer along an outer edge of the gates 12, showing the source region 18 doping, the p-well 14 doping, and the n-epi layer 32 doping.

FIG. 3 is a top-down view of the last three cells in the active region 15 (FIG. 1). The cells in this example are formed as elongated strips within the p-well 14. The cross-section of FIG. 1 is taken across the source regions 18 of FIG. 3.

As seen, the distance between the bottoms of the gate conductor within the trenches and the bottom of the p-well 14 has a significant effect on the operation of the device, since the distance affects the beta of the npn transistor and the turn-on voltage of the device. The dimensions of the trenches have a tolerance due to the masking and etching processes, and the depth of the p-well 14 also has tolerances due to implantation and drive-in processes. Any differences in trench depth or p-well 14 depth from lot to lot significantly affect at least the turn-on voltage for the device. It is generally important to have a consistent turn-on voltage and device characteristics from lot to lot.

A similar problem with variations in trench depth and p-well depth may occur with other trench-gated devices, and the invention is not limited to improvements to the device of FIG. 1.

What is needed is an improvement to a trench-gated structure, such as the device of FIG. 1 or any other IGBT, IGTO, thyristor, etc., so that the operating characteristics of the device are less sensitive to trench depth variations or variations in the depth of the p-well.

### SUMMARY

In one example of a silicon-based device improved by the present invention, the effective distance between the bottom of a gate trench and the bottom of a p-well (also referred to as a p-base or p-body) is made more consistent from lot to lot thereby making the operating characteristics of the devices more consistent.

In one example, the p-body is formed over an n-epi layer (drift layer), and an n+ source layer is formed over the p-body. Trenches are then etched that extend through the p-body and into the n-epi layer. This structure is in contrast to the prior art FIG. 1 where the trenches terminate within the p-body.

Next, a p-epitaxial layer is grown over the bottom and sidewalls of the trenches, such as by doping the epitaxial layer while it is being grown. The p-type epitaxial layer coating the trenches contacts the side of the p-body to effectively form a deeper portion of the original p-body. The p-epitaxial layer also contacts the exposed side of the source layer. The thickness and dopant concentration of the p-epitaxial layer are easily and precisely controlled.

Next, the p-epitaxial layer (silicon) in the trenches is exposed to an oxygen atmosphere to grown a thin gate oxide layer to insulate the inside of the trench. The growth of oxide is easily controlled.

Next, the insulated trenches are filled with a conductor, such as doped polysilicon.

The resulting structure has a trench whose gate conductor bottom is a precisely controlled distance from the p-epitaxial layer, where the p-epitaxial layer effectively forms the part of the p-body below and along the sides of the trench. The distance between the underlying n-epi layer (drift layer) and the gate is now dependent upon the thickness of the p-epitaxial layer formed within the trench rather than the variable thickness of the original p-body. Thus, the inherently-imprecise depths of the original p-body layer and the trench are not very significant in the resulting beta of the npn transistor or the turn-on voltage.

Other techniques for forming a precision p-layer abutting the trench may be used. A sacrificial layer containing p-dopants may be deposited in the trenches. The p-dopants are then diffused into the trench surfaces, and the sacrificial layer is then removed. The result is a precise p-layer along the bottom and sides of the trench that form a part of the p-body.

The p-dopants may also be implanted into the trench surfaces and diffused to form the p-layer that is part of the p-body.

The techniques may be used with many different types of cell arrays in a vertical insulated-gate device.

### BRIEF DESCRIPTION OF THE DRAWINGS

FIG. 1 is a cross-sectional view of the assignee's prior art vertical insulated-gate switch from U.S. Pat. No. 8,878,237, used to illustrate one possible device that can be improved using the present invention.

FIG. 2 shows the doping concentration vs. depth into the wafer of the device of FIG. 1 taken along the sides of trenches.

FIG. 3 is a top view of some cells in the device of FIG. 1.

FIGS. 4-9 illustrate steps during the fabrication of an improved IGTO device.

FIG. 4 is a cross-section showing an epitaxial n-drift layer, and overlying p-body layer, and an overlying source layer.

FIG. 5 illustrates an oxide layer and a silicon nitride layer formed over the source layer.

FIG. 6 illustrates trenches etched to extend below the p-body layer.

FIG. 7 illustrates a p-epitaxial layer grown along the bottom and sidewalls of the trenches to a desired thickness.

FIG. 8 illustrates the trenches being insulated by a gate oxide and a doped polysilicon deposited in the insulated trenches.

FIG. 9 illustrates a top metal electrode (a source electrode) formed on the top of the device.

FIG. 10 illustrates another embodiment where a sacrificial layer containing p-dopants is deposited in the trench, and the p-dopants are diffused into the trench walls.

FIG. 11 illustrates the structure of FIG. 10 with the p-dopants diffused into the silicon and the sacrificial layer removed. FIG. 11 can also be used to illustrate an embodiment, where p-dopants are implanted through the trench surfaces.

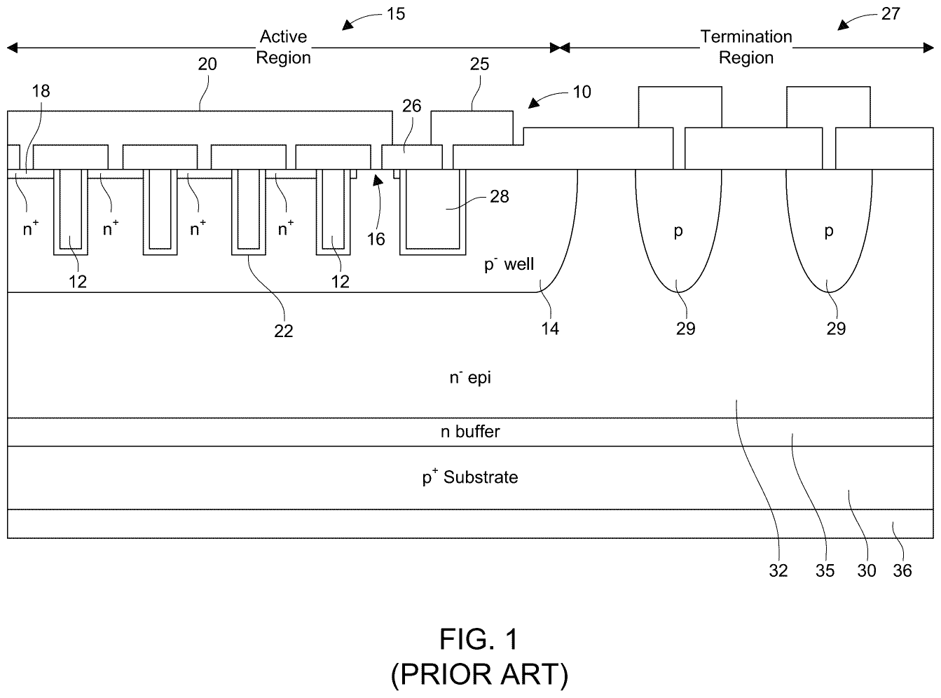

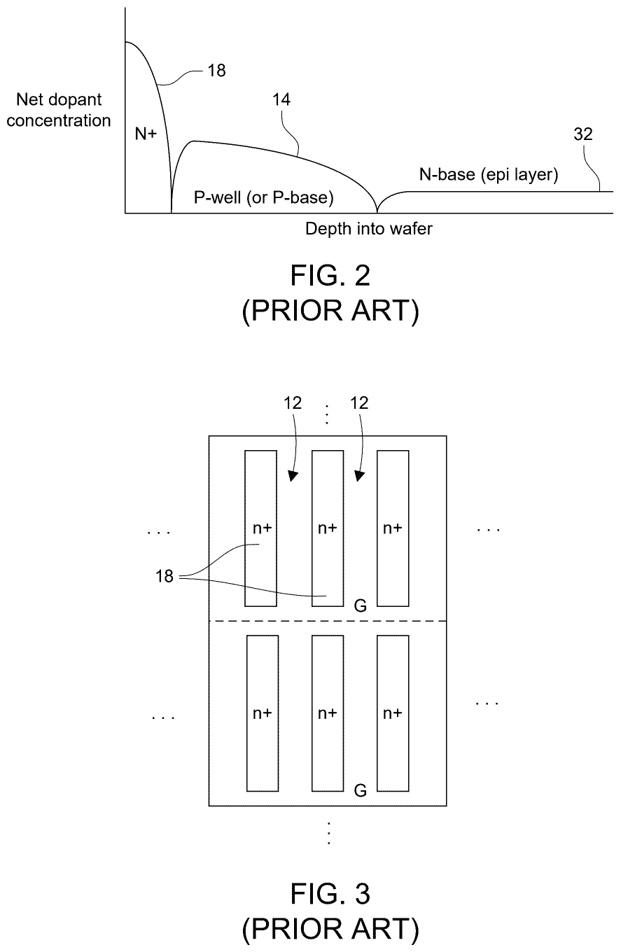

Conventional steps may be the same as those used for forming the device of FIG. 1 or related devices. The various techniques can be applied to different types of vertical, insulated gate devices.

Elements that are the same or equivalent are labelled with the same numerals.

### DETAILED DESCRIPTION

The invention is directed to an improved design of cells in a cellular vertical, insulated-gate device, such as an IGBT, IGTO, or thyristor device. The invention is particularly useful for high power devices used as switches.

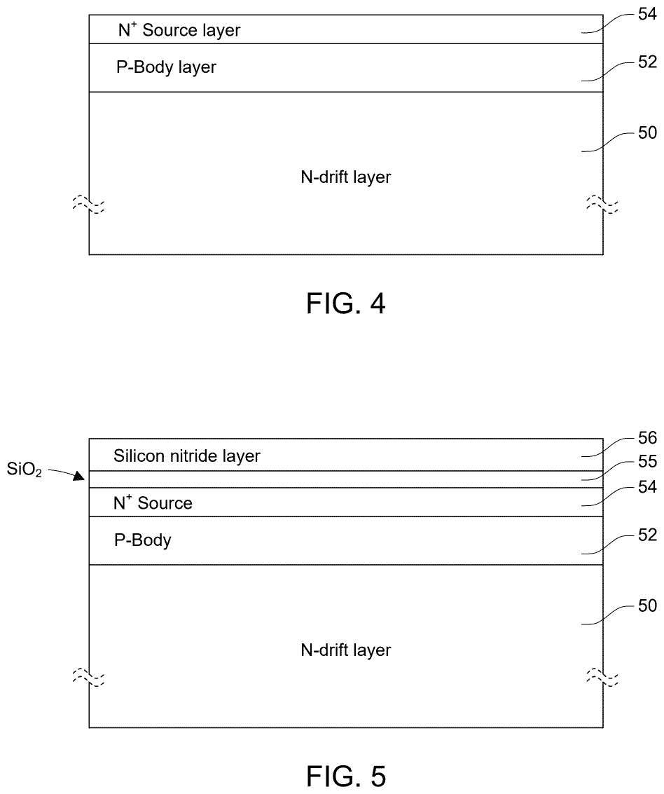

In FIG. 4, an n-drift layer 50 is epitaxially grown over a substrate (not shown). The substrate may be a p+ type, as shown in FIG. 1, or may be another type of substrate. The n-drift layer 50 may instead be part of a substrate, where the bottom surface of the substrate is then doped to form a p+ layer (a drain layer).

A p-body layer 52 is typically formed by implantation of p-type dopants into the surface of the n-drift layer 50. The dopants are then driven in to form the p-body 52 to have a desired depth and dopant concentration. The p-body layer 52 may be formed in other ways, such as being grown as a p-type epitaxial layer.

An n+ source layer 54 is then formed overlying the p-body layer 52. The source layer 54 is typically formed by implantation of n-type dopants into the surface of the p-body layer 52. The dopants are then driven in to form the source layer 54 to have a desired depth and dopant concentration. The thicknesses of all layers are dependent upon the desired characteristics of the device, and such thicknesses can be determined by simulation.

In FIG. 5, an oxide layer 55 (SiO2) is deposited, followed by depositing a silicon nitride layer 56. Such layers are dielectric layers.

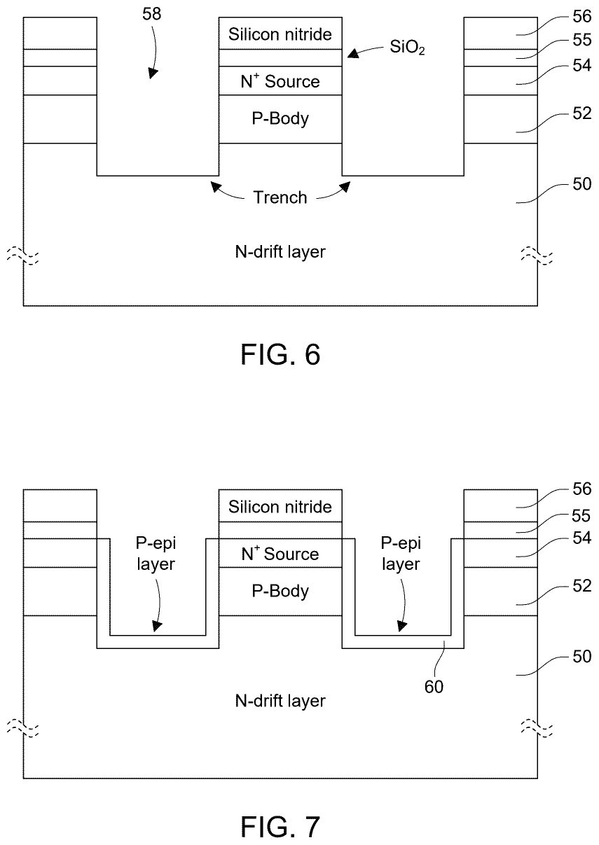

FIG. 6 illustrates the etching of gate trenches 58 using RIE. Note that the bottom of the trenches 58 is below the p-body layer 52, in contrast to FIG. 1.

FIG. 7 illustrates the growth of a silicon p-epitaxial layer 60 along the trench bottom and sidewalls. The thickness and dopant concentration of the p-epitaxial layer 60 can be precisely controlled. In the example shown, the top of the p-epitaxial layer 60 at the bottom of the trench 58 is still below the bottom of the p-body layer 52. The p-epitaxial layer 60 contacts the sides of the p-body layer 52 and source layer 54. The p-epitaxial layer 60 effectively forms an extension of the p-body layer 52 below the trenches 58, so the depth of the original p-body layer 52 has relatively little effect on the turn-on voltage of the device.

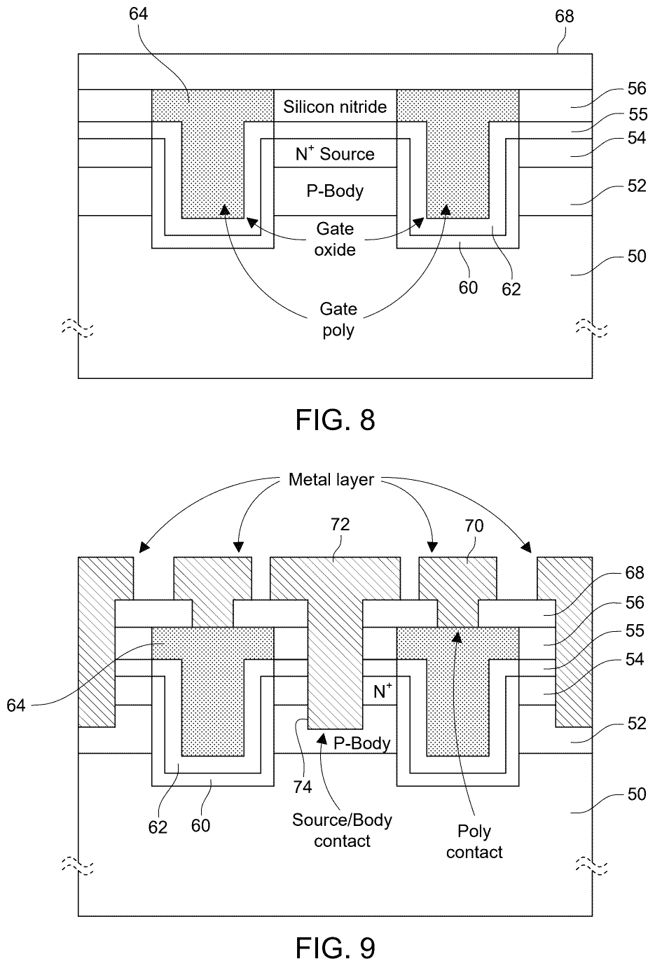

FIG. 8 illustrates the growth of a thin gate oxide layer 62 over the p-epitaxial layer 60. The gate oxide layer 62 can be grown to a precise thickness.

FIG. 8 also illustrates the deposition of doped polysilicon 64 within the trenches that is insulated from the p-epitaxial layer 60 by the gate oxide layer 62. The polysilicon 64 that is not within the trenches 58 is etched away.

A dielectric layer 68, such as a photoresist or oxide, is then deposited over the surface.

In FIG. 9, the dielectric layer 68 is patterned. Gate electrodes 70 contact the gate polysilicon 64, and source metal electrodes 72 contact the source layer 54 and p-body layer 52. A shallow trench 74 extends into the p-body layer 52, and the source metal electrodes 72 fill the shallow trench 74 to electrically contact the source layer 54 and p-body layer 52.

A metal drain electrode (shown in FIG. 1) is formed on the bottom side of the device, such as on a p+ surface of a silicon substrate.

When the source and drain voltage are the proper polarity and the gates are biased to a positive threshold voltage, a portion of the p-epitaxial layer 60 along the sides and bottom of the trench is inverted. Note that the top portion of the polysilicon 64 in the trench overlies a horizontal portion of the gate oxide 62. The horizontal portion of the p-epitaxial layer 64 below this horizontal portion of the gate oxide 62 inverts when the gate is biased above the threshold voltage, which creates a conductive horizontal channel between the source layer 54 and the remaining inverted region surrounding the gate.

When the gate is biased above the turn-on threshold voltage, causing the region surrounding the gate to be inverted, the p-type base of the npn transistor is effectively reduced, resulting in an increased beta of the npn transistor, and the turning on of the device, as described with respect to FIG. 1.

Since the thickness and dopant concentration of the p-epitaxial layer 60 in the trench 58 can be precisely controlled, the inversion layer can be precisely controlled. This inversion layer directly effects the width of the npn transistor base and its beta, which affects the turn-on voltage. Accordingly, compared to the device of FIG. 1, the turn-on voltage is not as dependent on the p-body 52 depth or the trench depth. Hence, the turn-on voltage is more repeatable from lot to lot.

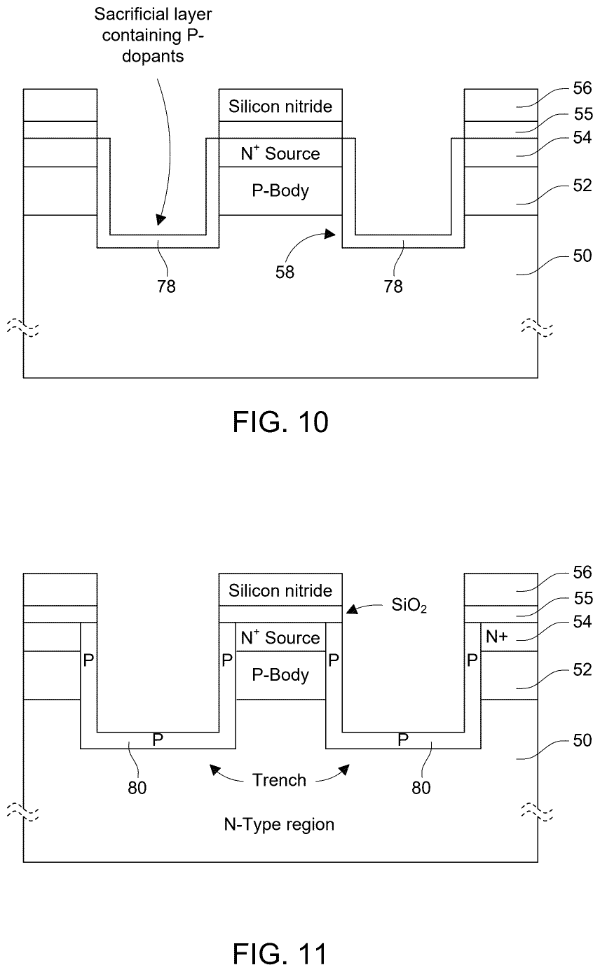

In another embodiment, shown in FIG. 10, instead of growing the p-epitaxial layer 60, a layer of p-type polysilicon 78 is deposited in the trenches 58.

In FIG. 11, the wafer is then heated to diffuse some of the p-type dopants into the regions below and adjacent to the trench walls, thus p-doping the n-drift layer 50 near the bottom of the trenches to form a p-layer 80, which effectively forms part of the p-body layer 52. The polysilicon is then oxidized to form a layer of oxide in the trench. The oxide is then etched away. The processes of FIGS. 8 and 9 are then carried out without the p-epitaxial layer 60.

In another embodiment, instead of growing the p-epitaxial layer 60, a layer of p-doped oxide is deposited in the trenches 58. This oxide may be represented by the layer 78 in FIG. 10. The wafer is then heated to diffuse some of the p-type dopants into the regions below and adjacent to the trench walls, thus p-doping the n-drift layer 50 near the bottom of the trenches to form a p-layer 80, which effectively forms part of the p-body layer 52. The oxide is then etched away. The processes of FIGS. 8 and 9 are then carried out without the p-epitaxial layer 60.

In another embodiment, also represented by FIG. 11, instead of growing the p-epitaxial layer 60, a plasma immersion implantation process (or other implant process) is carried out to inject p-type dopants into the bottom and sidewalls of the trenches 58. The wafer is then heated to diffuse the implanted p-type dopants into the regions below and adjacent to the trench walls, thus p-doping the n-drift layer 50 near the bottom of the trenches to form a p-layer 80, which effectively forms part of the p-body layer 52. The processes of FIGS. 8 and 9 are then carried out without the p-epitaxial layer 60.

Opposite conductivity type devices are formed by making dopant types the opposite of those describe above. Thus, the bottom of the device may be the cathode.

Although the examples given are in the context of modifications to the cells of the insulated-gate device of FIG. 1, the concepts can be applied to any vertical, insulated-gate, cellular power switch, such as IGTOs, IGBTs, thyristors, and other insulated-gate controlled devices.

The various techniques are simple to implement and those skilled in the art can easily modify masks or add process steps to implement the processes.

While particular embodiments of the present invention have been shown and described, it will be obvious to those skilled in the art that changes and modifications may be made without departing from this invention in its broader aspects and, therefore, the appended claims are to encompass within their scope all such changes and modifications as fall within the true spirit and scope of this invention.

What is claimed is:

1. An insulated gate-controlled device comprising:
a first semiconductor layer of a first conductivity type, the first semiconductor layer comprising a drift layer;
a second semiconductor layer of a second conductivity type overlying the first semiconductor layer, the second semiconductor layer forming a body region;
a third semiconductor layer of the first conductivity type overlying the second semiconductor layer, the third semiconductor layer forming source regions;
trenches extending through the body region and into the drift layer;
a fourth semiconductor layer of the second conductivity type contacting at least a bottom surface of the trenches, the fourth semiconductor layer being deeper than the body region and electrically coupled to the body region;
a gate oxide layer overlying the fourth semiconductor layer; and
a gate conductor within the trenches insulated by the gate oxide,
wherein applying a voltage to the gate conductor above a threshold voltage inverts portions of the fourth semiconductor layer along the bottom surface and sidewalls of the trench to turn on the device.

2. The device of claim 1 wherein the device forms a layered npnp device, forming an npn transistor and a pnp transistor, which are made vertically conductive by biasing the gate conductor above the threshold voltage.

3. The device of claim 2 wherein the third semiconductor layer forms an emitter for the npn transistor, the second semiconductor layer forms a base for the npn transistor, and the first semiconductor layer forms a collector for the npn transistor.

4. The device of claim 1 wherein the fourth semiconductor layer comprises a doped layer formed within the trenches along the bottom surface and sidewalls of the trenches.

5. The device of claim 4 wherein the doped layer is an epitaxially grown layer.

6. The device of claim 1 wherein the fourth semiconductor layer is formed below the bottom surface of trenches and along the sidewalls of the trenches.

7. The device of claim 6 wherein the fourth semiconductor layer comprises dopants of the second conductivity type implanted in the first semiconductor layer through the trenches.

8. The device of claim 6 wherein the fourth semiconductor layer comprises dopants of the second conductivity type diffused through the bottom surface and sidewalls of the trenches into the first semiconductor layer.

9. The device of claim 1 further comprising the fourth semiconductor layer abutting a side of the third semiconductor layer.

10. The device of claim 1 further comprising a source electrode contacting the third semiconductor layer.

11. The device of claim 1 wherein the first semiconductor layer is a layer in a growth substrate.

12. The device of claim 1 wherein the first semiconductor layer is epitaxially grown over a growth substrate.

13. The device of claim 1 further comprising a fifth semiconductor layer of the second conductivity type underlying the first semiconductor layer of the first conductivity type.

14. The device of claim 13 further comprising a drain electrode formed on the fifth semiconductor layer.

15. The device of claim 13 wherein the fifth semiconductor layer comprises a growth substrate.

16. A method of forming an insulated gate-controlled device comprising:
forming a first semiconductor layer of a first conductivity type, the first semiconductor layer comprising a drift layer;
forming a second semiconductor layer of a second conductivity type overlying the first semiconductor layer, the second semiconductor layer forming a body region;
forming a third semiconductor layer of the first conductivity type overlying the second semiconductor layer, the third semiconductor layer forming source regions;
etching trenches extending through the body region and into the drift layer;
forming a fourth semiconductor layer of the second conductivity type contacting at least a bottom surface of the trenches, the fourth semiconductor layer being deeper than the body region and electrically coupled to the body region;
forming a gate oxide layer overlying the fourth semiconductor layer; and
forming a gate conductor within the trenches insulated by the gate oxide,
wherein applying a voltage to the gate conductor above a threshold voltage inverts portions of the fourth semiconductor layer along the bottom surface and sidewalls of the trench to turn on the device.

17. The method of claim 16 wherein forming the fourth semiconductor layer comprises epitaxially growing a semiconductor layer of the second conductivity type within the trenches.

18. The method of claim 16 wherein forming the fourth semiconductor layer comprises depositing a layer containing dopants of the second conductivity type within the trenches, and diffusing the dopants of the second conductivity type into the first semiconductor layer.

19. The method of claim 16 wherein forming the fourth semiconductor layer comprises implanting dopants of the second conductivity type into the bottom surface and sidewalls of the trenches, and diffusing the dopants of the second conductivity type into the first semiconductor layer.

20. The method of claim 16 wherein forming the fourth semiconductor layer comprises depositing a layer of oxide containing dopants of the second conductivity type within the trenches, diffusing the dopants of the second conductivity type into the first semiconductor layer, then removing the oxide.
